(19) United States
(12) Patent Application Publication
(10) Pub. No.: US 2024/0162359 A1
(43) Pub. Date: May 16, 2024

(54) BACKSHEET OF SOLAR CELL MODULE AND SOLAR CELL MODULE INCLUDING THEREOF

(71) Applicant: Industrial Technology Research Institute, Hsinchu (TW)

(72) Inventors: Chih-Kang Peng, Miaoli County (TW); Cheng-Hsuan Lin, Hsinchu City (TW); Yu-Ling Hsu, Hsinchu City (TW); Chun-Chen Chiang, Hsinchu City (TW)

(73) Assignee: Industrial Technology Research Institute, Hsinchu (TW)

(21) Appl. No.: 18/151,488

(22) Filed: Jan. 9, 2023

(30) Foreign Application Priority Data
Nov. 11, 2022 (TW) 111143090

(51) Int. Cl. H01L 31/049; H01L 31/048

(52) U.S. Cl. CPC H01L 31/049; H01L 31/0481; H01L 31/053

(57) ABSTRACT

A backsheet of a solar cell module including a substrate, a first protection layer, and a second protection layer is provided. The substrate includes a first surface and a second surface opposite to each other. The first protection layer is disposed on the first surface of the substrate. The second protection layer is disposed on the second surface of the substrate, wherein the first protection layer and the second protection layer include a silicone layer. At least one of the first protection layer and the second protection layer includes diffusion particles, wherein the diffusion particles include zinc oxide, titanium dioxide modified with silicon dioxide, or a combination thereof. A thickness of the first protection layer and a thickness of the second protection layer are respectively 10 μm to 30 μm. A solar cell module including the backsheet is also provided.

### CROSS-REFERENCE TO RELATED APPLICATION

This application claims the priority benefit of Taiwan application serial no. 111143090, filed on Nov. 11, 2022. The entirety of the above-mentioned patent application is hereby incorporated by reference herein and made a part of this specification.

### TECHNICAL FIELD

The disclosure relates to a backsheet of a solar cell module and a solar cell module including the backsheet, and in particular relates to a backsheet including diffusion particles and non-fluorine material of a solar cell module and a solar cell module including the backsheet.

### BACKGROUND

A solar cell module that receives light on both sides is a solar cell that may generate electricity on both sides, in which the backsheet of the solar cell module performs light conversion by absorbing the light reflected or scatter-diffused by the ground. Therefore, for the consideration of the material of the backsheet, in addition to having high light transmittance, it is also one of the key points such that the light may be diffused (scattered) in the backsheet so that the battery units may absorb uniform light.

In addition, the currently commonly used material of the backsheet is a fluorine-containing resin layer, which may protect the battery units in the solar cell module because of its weather resistance. However, when the backsheet has to be recycled, burying the fluorine-containing resin layer causes damage to the environment, and when the fluorine-containing resin layer is incinerated or degraded, it causes harm to the human body due to the emission of fluorine-containing substances.

At present, there is an urgent need to develop a backsheet with a solar cell module that may diffuse (scatter) light therein; and reduce the harm to the environment and human body caused by the backsheet under the condition of being weather resistance.

### SUMMARY

The disclosure provides a backsheet of a solar cell module and a solar cell module including the backsheet. The backsheet may diffuse light therein and reduce the harm to the environment and human body under the condition of being weather resistance.

The backsheet of the solar cell module of the disclosure includes a substrate, a first protection layer, and a second protection layer. The substrate includes a first surface and a second surface opposite to each other. The first protection layer is disposed on the first surface of the substrate. The second protection layer is disposed on the second surface of the substrate, in which the first protection layer and the second protection layer include a silicone layer. At least one of the first protection layer and the second protection layer includes diffusion particles, in which the diffusion particles include zinc oxide, titanium dioxide modified with silicon dioxide, or a combination thereof. A thickness of the first protection layer and a thickness of the second protection layer are respectively 10 μm to 30 μm.

The solar cell module of the disclosure includes a battery unit, a backsheet, and an adhesive layer. The backsheet is disposed on the battery unit and includes a substrate, a first protection layer, and a second protection layer. The substrate includes a first surface and a second surface opposite to each other, in which the second surface faces the battery unit. The first protection layer is disposed on the first surface of the substrate. The second protection layer is disposed on the second surface of the substrate, in which the first protection layer and the second protection layer include a silicone layer. At least one of the first protection layer and the second protection layer includes diffusion particles, in which the diffusion particles include zinc oxide, titanium dioxide modified with silicon dioxide, or a combination thereof. A thickness of the first protection layer and a thickness of the second protection layer are 10 μm to 30 μm. The adhesive layer is disposed between the battery unit and the second protection layer.

Based on the above, the backsheet of the solar cell module of the disclosure includes a first protection layer away from the battery units and a second protection layer facing the battery units. By adding specific diffusion particles to at least one of the first protection layer and the second protection layer, the intensity and uniformity of light incident on the battery units through the backplane may be improved, so that the amount of light received by the battery units may be increased, thereby improving the light conversion efficiency of solar cell modules. Furthermore, the disclosure uses the silicone layer as the base of the first protection layer and the second protection layer, which not only weather resistant, but also reduces pollution to the environment.

### BRIEF DESCRIPTION OF THE DRAWING

FIG. 1A is a partial cross-sectional schematic diagram of a solar cell module of an embodiment of the disclosure.

FIG. 1B is a partial cross-sectional schematic diagram of a backsheet of a solar cell module of an embodiment of the disclosure.

FIG. 2A is a partial cross-sectional schematic diagram of a solar cell module of another embodiment of the disclosure.

FIG. 2B is a partial cross-sectional schematic diagram of a backsheet of a solar cell module of another embodiment of the disclosure.

FIG. 3 is a graph of the light transmittance of the backsheet in the solar cell module and the light spot size gain value of the backsheet as a function of the content of diffusion particles of an embodiment of the disclosure.

FIG. 4A is an image of alight spot produced by a backsheet in a solar cell module without diffusion particles.

FIG. 4B is an image of a light spot generated by a backsheet in a solar cell module including diffused particles of an embodiment of the disclosure.

FIG. 5 is a graph showing the relationship between the intensity of the light received by the light sensor and the position of the light spot according to FIG. 4A and FIG. 4B.

FIG. 6 is a graph of the light transmittance of the backsheet in the solar cell module and the light spot size gain value of the backsheet as a function of the content of diffusion particles of another embodiment of the disclosure.

FIG. 7 is a graph showing the relationship between the light transmittance of the backsheet and the particle size of titanium dioxide modified with silicon dioxide.

FIG. 8 is a graph of the light transmittance of the backsheet in the solar cell module and the light spot size gain value of the backsheet as a function of the content of diffusion particles of the comparative experimental example of the disclosure.

### DETAILED DESCRIPTION OF DISCLOSED EMBODIMENTS

The disclosure may be understood by referring to the following detailed description in conjunction with the accompanying drawings. It should be noted that, for the ease of understanding by the readers and for the brevity of the accompanying drawings, multiple drawings in the disclosure only depict a portion of the electronic device, and the specific elements in the drawings are not drawn according to the actual scale. In addition, the number and size of each of the elements in the figures are for illustration purposes only, and are not intended to limit the scope of the disclosure.

In the disclosure, wordings used to indicate directions, such as “up,” “down,” “front,” “back,” “left,” and “right,” merely refer to directions in the accompanying drawings. Therefore, the directional wordings are used to illustrate rather than limit the disclosure. In the accompanying drawings, the drawings illustrate the general features of the methods, structures, and/or materials used in the particular embodiments. However, the drawings shall not be interpreted as defining or limiting the scope or nature covered by the embodiments. For example, the relative sizes, thicknesses, and locations of the layers, regions, and/or structures may be reduced or enlarged for clarity.

When a corresponding component (e.g., a film layer or region) is referred to as being “on” another component, it may be directly on the other component or other components may be present therebetween. On the other hand, when a component is referred to as being “directly on” another member, there are no components in between. Additionally, when a component is referred to as being “on” another component, the two are in a top-down relationship when viewed from above, and the component may be above or below the other component, depending on the orientation of the device.

The terms “about”, “equal to”, “equal” or “same”, “substantially” or “generally” are interpreted as within 20% of a given value or range, or interpreted as within 10%, 5%, 3%, 2%, 1%, or 0.5% of the given value or range.

The terms such as “first”, “second”, etc. used in the description and the patent claims are used to modify elements, which do not imply and represent that the (or these) elements have any previous ordinal numbers, and also does not represent the order of a certain element and another element, or the order of the manufacturing method. The use of these ordinal numbers is to only clearly distinguish an element with a certain name from another element with the same name. The same terms may not be used in the patent claims and the description, and accordingly, the first component in the description may be the second component in the patent claims.

It should be noted that, in the following embodiments, the features in several different embodiments may be replaced, reorganized, and mixed to complete other embodiments without departing from the spirit of the disclosure. As long as the features of the various embodiments do not violate the spirit of the disclosure or conflict with one another, they may be mixed and matched arbitrarily.

Exemplary embodiments of this disclosure are exemplified below, the same reference numerals in the drawings and the descriptions indicate the same or similar parts.

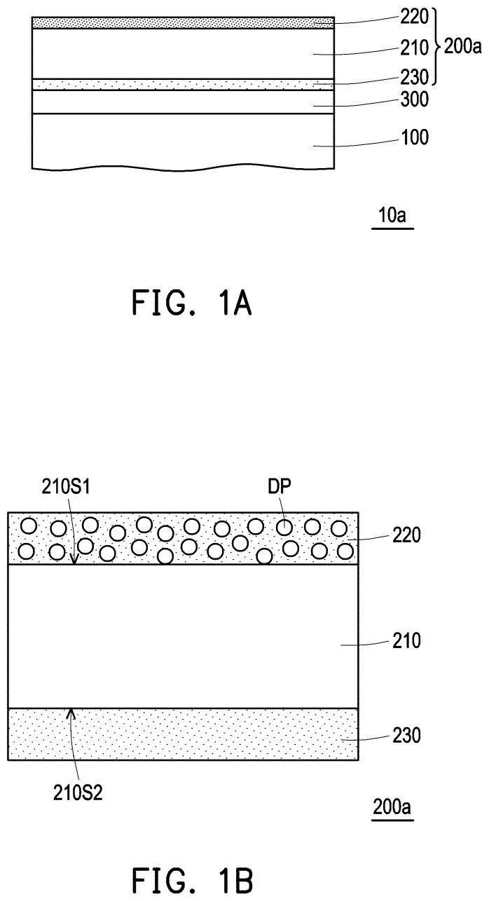

FIG. 1A is a partial cross-sectional schematic diagram of a solar cell module of an embodiment of the disclosure, and FIG. 1B is a partial cross-sectional schematic diagram of a backsheet of a solar cell module of an embodiment of the disclosure.

Referring to FIG. 1A and FIG. 1B simultaneously, the solar cell module 10a of this embodiment includes a battery unit 100, a backsheet 200a, and an adhesive layer 300.

In this embodiment, the battery unit 100 is a battery unit that receives light on both sides. That is, the surface of the battery unit 100 facing the backsheet 200a may also absorb, for example, light reflected or scatter diffused by the ground, but the disclosure is not limited thereto. The battery unit 100 may, for example, at least include a photoelectric conversion layer (not shown) and two electrodes (not shown) disposed on opposite surfaces of the photoelectric conversion layer, but the disclosure is not limited thereto. In some embodiments, the battery unit 100 may include a silicon solar cell, but the disclosure is not limited thereto.

The backsheet 200a is, for example, disposed on the battery unit 100, and may, for example, be used for supporting and protecting the battery unit 100. For example, the backsheet 200a may have the functions of weather resistance such as UV resistance, water and oxygen resistance, and heat resistance, but the disclosure is not limited thereto. In addition, the backsheet 200a of this embodiment may also have high light transmittance, which may increase the amount of light received by the battery unit 100. The reason why the backsheet 200a has high light transmittance is described in detail below.

In this embodiment, the backsheet 200a includes a substrate 210, a first protection layer 220, and a second protection layer 230. The light transmittance of the backsheet 200a is greater than 89%, and the light spot size gain value of the backsheet 200a is greater than 20%, so that the solar cell module 10a has high light conversion efficiency. For the measurement method of the light transmittance of the backsheet 200a and the light spot size gain value of the backsheet 200a, refer to the following experimental example.

The substrate 210 may include, for example, a transparent thermoplastic resin, so that the backsheet 200a has high light transmittance. For example, the material of the substrate 210 may include polyethylene terephthalate (PET), but the disclosure is not limited thereto. In other embodiments, the material of the substrate 210 may include poly(methyl methacrylate) (PMMA). In some embodiments, the thickness of the substrate 210 is greater than or equal to 250 μm.

The first protection layer 220 is, for example, disposed on the first surface 210S1 of the substrate 210. In this embodiment, the base of the first protection layer 220 includes a silicone layer. The silicone layer may have the aforementioned function of weather resistance due to the silicon-oxygen bond skeleton (—Si—O—Si—) it includes. The material included in the silicone layer is not particularly limited. For example, the silicone layer may include polysiloxane resin, silicone, or a combination thereof. In addition, the silicone layer also has high light transmittance.

In this embodiment, the first protection layer 220 further includes diffusion particles DP. The diffusion particles DP may, for example, scatter the light entering the first protection layer 220, so that the subsequent light entering the battery unit 100 through the substrate 210 may be more uniform. That is, the amount of light received by multiple battery elements (not shown) in the battery unit 100 may be relatively close to each other. Furthermore, the diffusion particles DP may change the path of light with a larger incident angle, so that most of the light may be guided to the battery unit 100 instead of being reflected by the first protection layer 220. Therefore, the first protection layer 220 including the diffusion particles DP may increase the amount of light received by the battery unit 100, thereby improving the light conversion efficiency of the solar battery module 10a. In this embodiment, the material of the diffusion particles DP includes zinc oxide, titanium dioxide modified with silicon dioxide, or a combination thereof. In addition, in this embodiment, the content of the diffusion particles DP in the first protection layer 220 is 0.05 wt % to 0.5 wt %. When the diffusion particles DP include the aforementioned materials and/or the aforementioned contents, the amount of light received by the battery unit 100 may be increased, which is described in detail in the following experimental examples. In some embodiments, the difference between the refractive index of the diffusion particles DP and the refractive index of the silicone layer is greater than 0.3, and the particle size range of the diffusion particles DP is 0.5 m to 5 μm, so that the diffusion particles DP have high light scattering effect.

In addition, in this embodiment, the thickness of the first protection layer 220 is 10 m to 30 μm. When the first protection layer 220 has a thickness in the aforementioned range, the amount of light received by the battery unit 100 may be increased, which is described in detail in the following experimental examples.

The second protection layer 230 is, for example, disposed on the second surface 210S2 of the substrate 210. In this embodiment, the first surface 210S1 and the second surface 210S2 of the substrate 210 are opposite to each other. In detail, the first surface 210S1 of the substrate 210 is, for example, away from the battery unit 100, and the second surface 210S2 of the substrate 210 is, for example, facing the battery unit 100. In this embodiment, the second protection layer 230 includes the aforementioned silicone layer. That is, the second protection layer 230 may be made of the same or similar material as the silicone layer included in the first protection layer 220, and details are not described herein again. In addition, in this embodiment, the thickness of the second protection layer 230 is 10 μm to 30 μm.

The adhesive layer 300 is, for example, disposed between the battery unit 100 and the second protection layer 230 of the backsheet 200a. The adhesive layer 300 may, for example, be used to adhere the battery unit 100 to the backsheet 200a. In some embodiments, the material of the adhesive layer 300 may include thermoplastic resin or thermosetting resin, which is not particularly limited in the disclosure. For example, the material of the adhesive layer 300 may include ethylene vinyl acetate (EVA).

In some embodiments, the backsheet 200a may be prepared by, for example, the following methods, but the disclosure is not limited thereto. For example, the diffusion particles DP are uniformly dispersed in the silicone layer. After it is uniformly dispersed, it is coated on the first surface 210S1 of the substrate 210 and cured to form the first protection layer 220. In addition, after another silicone layer is coated on the second surface 210S2 of the substrate 210 and cured, the second protection layer 230 is formed.

In some embodiments, the solar cell module 10a may also include a front sheet (not shown). The front sheet may be adhered to the battery unit 100, for example, by another adhesive layer (not shown). The material of the substrate of the front sheet may be, for example, the same as or similar to the material of the aforementioned substrate 210, but the disclosure is not limited thereto. In other embodiments, the material of the substrate of the front sheet may be glass.

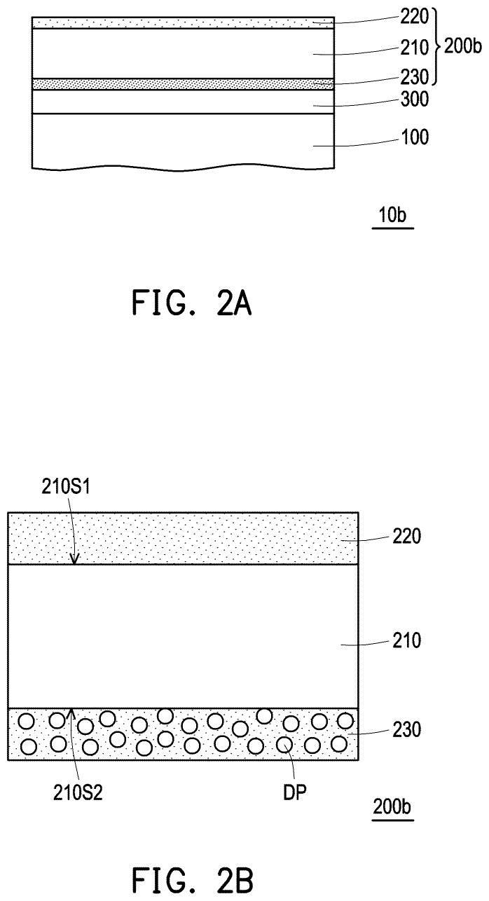

FIG. 2A is a partial cross-sectional schematic diagram of a solar cell module of another embodiment of the disclosure, and FIG. 2B is a partial cross-sectional schematic diagram of a backsheet of a solar cell module of another embodiment of the disclosure.

Referring to FIG. 2A and FIG. 2B simultaneously, the main difference between the solar cell module 10b of this embodiment and the solar cell module 10a shown in FIG. 1 is that the diffusion particles DP are added to the second protection layer 230 in the backsheet 200b, but not to the first protection layer 220 in the backsheet 200b.

It should be noted that, although not shown in FIG. 2A and FIG. 2B, in other embodiments, the diffusion particles DP may be simultaneously added to the first protection layer 220 and the second protection layer 230.

### Experimental Example

The disclosure is described below by means of experimental examples, but these experimental examples are only used for illustration and are not intended to limit the scope of the disclosure.

### Experimental Example 1

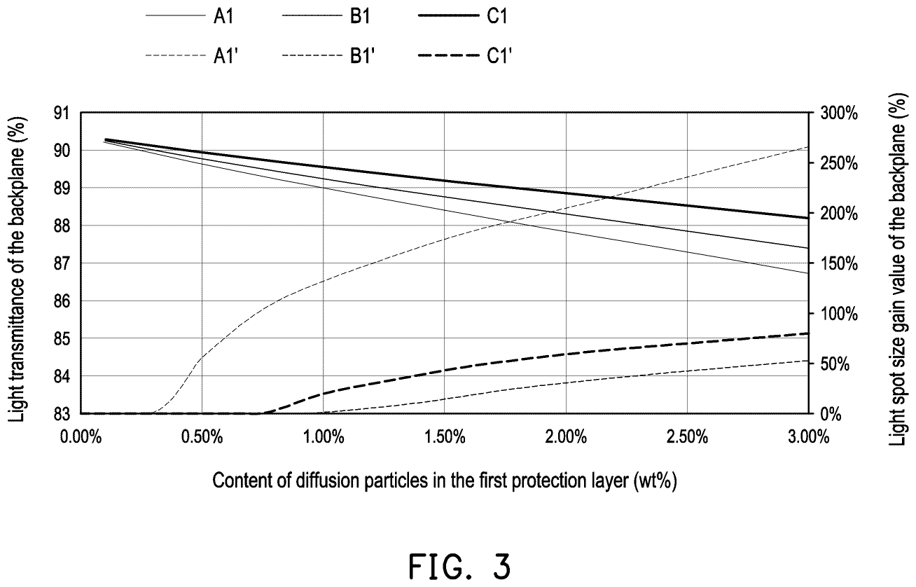

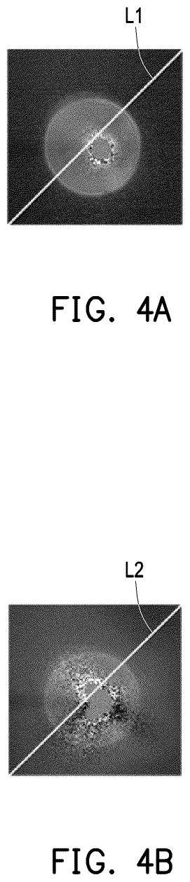

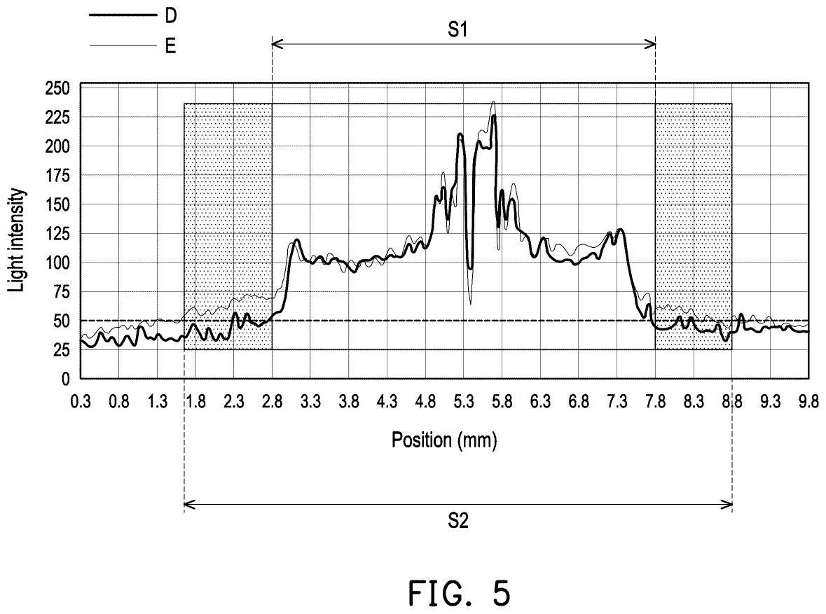

FIG. 3 is a graph of the light transmittance of the backsheet in the solar cell module and the light spot size gain value of the backsheet as a function of the content of diffusion particles of an embodiment of the disclosure, FIG. 4A is an image of a light spot produced by a backsheet in a solar cell module without diffusion particles, FIG. 4B is an image of a light spot generated by a backsheet in a solar cell module including diffused particles of an embodiment of the disclosure, and FIG. 5 is a graph showing the relationship between the intensity of the light received by the light sensor and the position of the light spot according to FIG. 4A and FIG. 4B.

It is worth noting that the light transmittance of the backsheet mentioned here may be expressed by the following formula: (Fout/Fin)*100%, in which Fout is the luminous flux of light passing through the backsheet, and Fin is the luminous flux of light incident on the backsheet. In addition, the light spot size gain value of the backsheet mentioned here may be expressed by the following formula: ((LD-LND)/LND)*100%, in which LD is the light spot diameter generated on the light-receiving surface of the battery unit by the light passing through the backsheet including diffusion particles, and LND is the light spot diameter generated on the light-receiving surface of the battery unit by the light passing through the backsheet without diffusion particles. In this experimental example, the light transmittance of the backsheet is defined to be greater than 89%, and the light spot size gain value of the backsheet is defined to be greater than 20%.

The solar cell module of this experimental example is constructed by ASAP optical analysis simulation software, but the disclosure is not limited thereto.

The light transmittance may be measured, for example, according to ASTM D1003, and the light spot size gain value may be measured, for example, in the following manner, but the disclosure is not limited thereto.

For example, first, the light sensor (replaced with a battery unit here) is attached to the backsheet, the light sensor is connected to the computer, and laser light is used to irradiate the first protection layer of the backsheet (incidence angle is 0 degrees), in which the backsheet does not include diffusion particles, and then the computer is used to store the image of the light received in the light sensor, as shown in FIG. 4A; then, the light sensor is attached to another backsheet, so that the laser light irradiates the first protection layer of the other backsheet (incidence angle is 0 degrees), in which the backsheet includes diffusion particles, and then the computer is used to store the image of the light received in the light sensor, as shown in FIG. 4B. Then, the computer is used to respectively display the aforementioned images of the light received in the light sensor, and respectively analyze the intensity of the light received at each position of the light sensor. The line segment L1 and the line segment L2 respectively represent the position where the light sensor receives light in FIG. 5. As shown in FIG. 5, the curve D is the light intensity at each position sensed by the light sensor bonded to the backsheet without diffusion particles, and the curve E is the light intensity at each position sensed by the light sensor bonded to the backsheet including diffusion particles. It should be noted here that the optical sensor of this embodiment has a built-in analog-to-digital converter (ADC) circuit, which has an 8-bit resolution and may encode the analog signal into 256 different discrete values (e.g., 0 to 255), the light sensor displays 8-bit grayscale image. In this embodiment, 50 is used as the boundary threshold, that is, when the intensity of the output signal is less than 50, the output signal belongs to the background signal.

It may be seen from FIG. 4A, FIG. 4B, and FIG. 5, taking 50 as the boundary of the light intensity, the position greater than 50 in the curve D as the region S1, and the position greater than 50 in the curve E as the region S2, for the backsheet of the solar cell added with diffusion particles, the size of the light spot obtained on the light sensor increases significantly (region S2>region S1), which means that the addition of diffusion particles may uniformly diffuse the light incident on the backsheet, thereby, the amount of light received by the solar cell may be increased.

In Experimental Example 1 shown in FIG. 3, the backsheet of the solar cell module used has the structure of the solar cell module shown in FIG. 1B or FIG. 2B, and has the following formation.

The material of the substrate is ethylene terephthalate, the refractive index of the substrate is 1.66, and the thickness of the substrate is 250 μm.

The thickness of the first protection layer is 25 μm, the material of the silicone layer in the first protection layer is polysiloxane resin (purchased from Ecoway Technology Co., Ltd., model: ECO901), the refractive index of the silicone layer is 1.44, and the density of the silicone layer is 1.2 g/cm³.

The material of the diffusion particles is zinc oxide (purchased from Yung Chyang Chemical Industries Corp., Ltd., model: SHG), the refractive index of the diffusion particles is 1.9, and the density of the diffusion particles is 5.61 g/cm³.

The thickness of the second protection layer is 10 μm, the material of the silicone layer in the second protection layer is polysiloxane resin (purchased from Ecoway Technology Co., Ltd., model: ECO901), the refractive index of the silicone layer is 1.44, and the density of the silicone layer is 1.2 g/cm³.

The material of the adhesive layer is ethylene-vinyl acetate copolymer, the refractive index of the adhesive layer is 1.4845, and the thickness of the adhesive layer is 275 μm.

In Experimental Example 1 shown in FIG. 3, the light transmittance and the light spot size gain value of the backsheet including the diffusion particles with different particle sizes are measured, in which the curve A1, the curve B1, and the curve C1 are respectively the relationship curve between the light transmittance and the content of the diffusion particles for the backsheet including the diffusion particles of 0.70 μm, 0.95 μm, and 1.20 am, and the curve A1′, the curve B1′ and the curve C1′ are respectively the relationship curve between the light spot size gain value and the content of the diffusion particles for the backsheet including the diffusion particles of 0.70 μm, 0.95 μm, and 1.20 μm.

It may be seen from FIG. 3 that (1) as the added content of diffusion particles in the first protection layer increases, the light spot size gain value of the backsheet of the solar cell module increases, but the light transmittance of the backsheet of the solar cell module increases; (2) the larger the particle size of the diffusion particles, the smaller the decrease in the light transmittance of the backsheet of the solar cell module when the added content of diffusion particles is increased, but the light spot size gain value of the backsheet of the solar cell module is accordingly reduce; (3) the refractive index of the diffusion particles (zinc oxide) is 1.9, and there is an suitable refractive index difference (0.46) between the diffusion particles and the silicone layer, so that the backsheet of the solar cell module may exhibit high light transmittance; (4) in the case that the backsheet of the solar cell module must have a light transmittance greater than 89%, the added content of diffusion particles (zinc oxide) with a particle size of 0.70 μm in the first protection layer must be at least <1%.

### Experimental Example 2

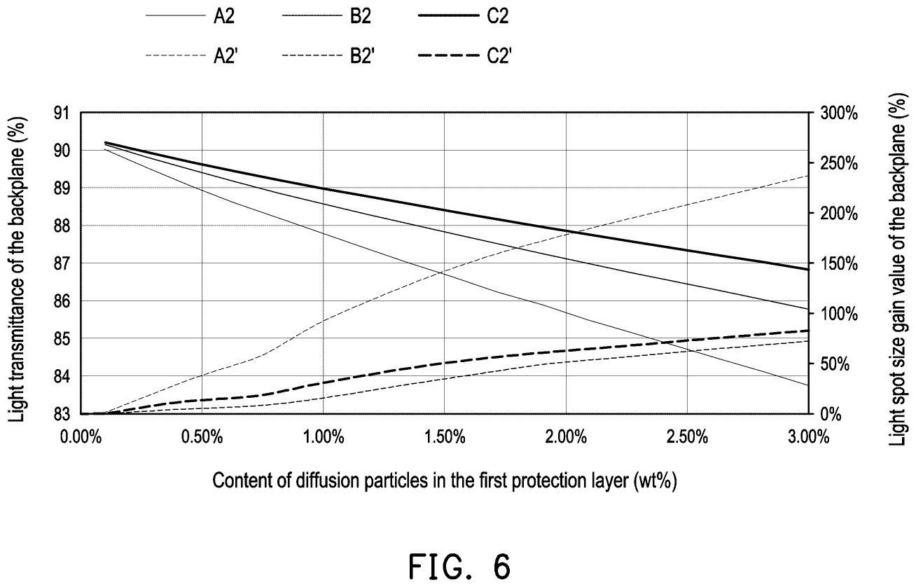

FIG. 6 is a graph of the light transmittance of the backsheet in the solar cell module and the light spot size gain value of the backsheet as a function of the content of diffusion particles of another embodiment of the disclosure.

In Experimental Example 2 shown in FIG. 6, the backsheet of the solar cell module used has the structure of the solar cell module shown in FIG. 1B or FIG. 2B, and has a formation similar to that of Experimental Example 1 shown in FIG. 3. The difference is that the diffusion particles used in Experimental Example 2 shown in FIG. 6 are titanium dioxide modified with silicon dioxide (purchased from World Chem Industries Co., Ltd., model: Altiris 800), the refractive index of the diffusion particles is 2.45, and the density of the diffused particles is 4.23 g/cm³.

In Experimental Example 2 shown in FIG. 6, the light transmittance and the light spot size gain value of the backsheet including the diffusion particles with different particle sizes are measured, in which the curve A2, the curve B2, and the curve C2 are respectively the relationship curve between the light transmittance and the content of the diffusion particles for the backsheet including the diffusion particles of 0.70 μm, 0.95 μm, and 1.20 μm, and the curve A2′, the curve B2′ and the curve C2′ are respectively the relationship curve between the light spot size gain value and the content of the diffusion particles for the backsheet including the diffusion particles of 0.70 μm, 0.95 μm, and 1.20 μm.

It may be seen from FIG. 6 that (1) as the added content of diffusion particles in the first protection layer increases, the light spot size gain value of the backsheet of the solar cell module increases, but the light transmittance of the backsheet of the solar cell module increases; (2) the larger the particle size of the diffusion particles, the smaller the decrease in the light transmittance of the backsheet of the solar cell module when the added content of diffusion particles is increased, but the light spot size gain value of the backsheet of the solar cell module is accordingly reduce; (3) the refractive index of the diffusion particles (titanium dioxide modified with silicon dioxide) is 2.45, and a suitable refractive index difference between the diffusion particles and the silicone resin layer is 1.01, which enables the backsheet of the solar cell module to exhibit relatively poor light transmittance compared with Experimental Example 1 shown in FIG. 3; (4) in the case that the backsheet of the solar cell module must have a light transmittance greater than 89%, the added content of diffusion particles (titanium dioxide modified with silicon dioxide) with a particle size of 0.70 μm in the first protection layer must be at least <0.5%.

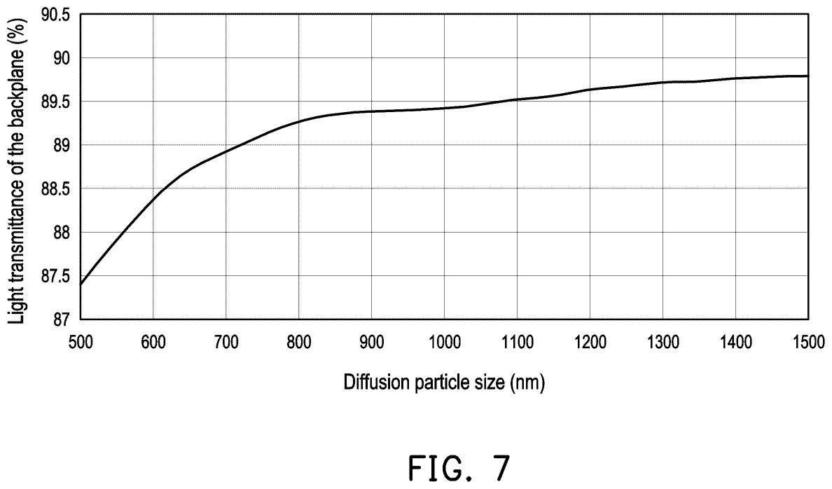

In addition, FIG. 7 is a graph showing the relationship between the light transmittance of the backsheet and the particle size of titanium dioxide modified with silicon dioxide. It may be seen from FIG. 7 that the particle size of the titanium dioxide modified with silicon dioxide must be at least greater than 700 nm (0.70 μm) when the light transmittance of the backsheet of the solar cell module is required to be greater than 89%.

### Comparative Experimental Example

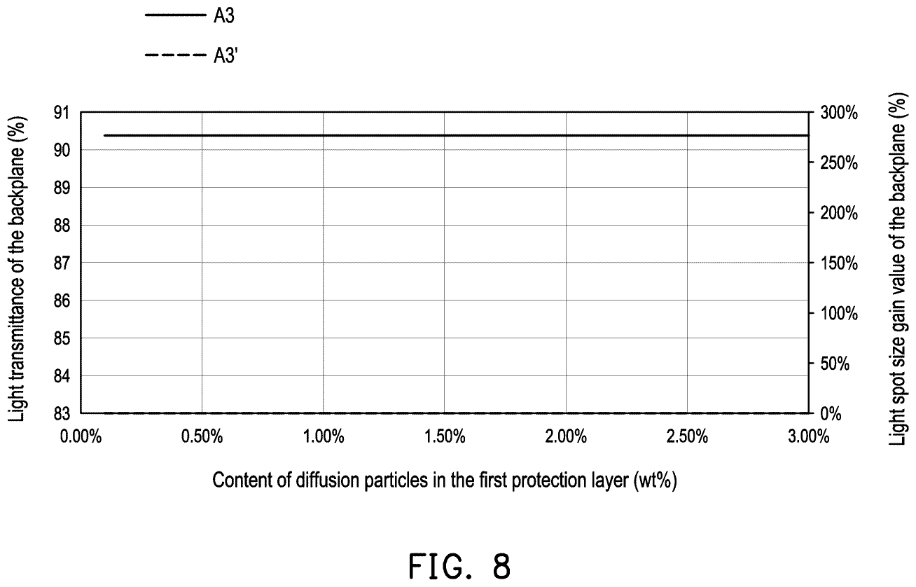

FIG. 8 is a graph of the light transmittance of the backsheet in the solar cell module and the light spot size gain value of the backsheet as a function of the content of diffusion particles of the comparative experimental example of the disclosure.

In Comparative Experimental Example shown in FIG. 8, the backsheet of the solar cell module used has the structure of the solar cell module shown in FIG. 1B or FIG. 2B, and has a formation similar to that of Experimental Example 1 shown in FIG. 3. The difference is that the diffusion particles used in Comparative Experimental Example shown in FIG. 8 are silicon dioxide (purchased from Soken, model: SRP-200S), the refractive index of the diffusion particles is 1.457, and the density of the diffused particles is 2.65 g/cm³.

In Comparative Experimental Example shown in FIG. 8, the light transmittance and the light spot size gain value of the backsheet including diffusion particles are measured, in which the curve A3 is the relationship curve between the light transmittance and the content of the diffusion particles for the backsheet including the diffusion particles of 1.20 μm, and the curve A3′ is the relationship curve between the light spot size gain value and the content of the diffusion particles for the backsheet including the diffusion particles of 1.20 μm.

It may be seen from FIG. 8, (1) the light spot size gain value and the light transmittance of the backsheet of the solar cell module are independent of the added content of the diffusion particles (silicon dioxide) in the first protection layer; (2) the refractive index difference between the diffusion particles (silicon dioxide) and the silicone layer is only 0.017, so there is no light diffusion effect.

### Experimental Example 3

After integrating the experimental data of the above Experimental Example 1, Experimental Example 2, and Comparative Experimental Example, the disclosure is further described by the following embodiments, but these embodiments are only used for illustration and are not intended to limit the scope of the disclosure.

### Embodiment 1

In this embodiment, the solar cell module has a similar structure and formation as shown in Experimental Example 1, the only difference is that the thickness of the first protection layer is m, the diffusion particles (zinc oxide) are added to the first protection layer, the particle size of the diffusion particles is 0.75 μm, and the content of the diffusion particles is 0.1 wt %. In addition, the light transmittance, light spot size gain value, and haze of the backsheet of this embodiment are measured, in which the haze may be measured according to, for example, ASTM D-1003, but the disclosure is not limited thereto.

### Embodiment 2

This embodiment is substantially the same as the rest of Embodiment 1, except that the diffusion particles are added to the second protection layer.

### Embodiment 3

This embodiment is substantially the same as the rest of Embodiment 1, except that the content of diffusion particles is 0.3 wt %.

### Embodiment 4

This embodiment is substantially the same as the rest of Embodiment 2, except that the content of diffusion particles is 0.3 wt %.

### Embodiment 5

This embodiment is substantially the same as the rest of Embodiment 1, except that the content of diffusion particles is 0.5 wt %.

### Embodiment 6

This embodiment is substantially the same as the rest of Embodiment 2, except that the content of diffusion particles is 0.5 wt %.

### Embodiment 7

This embodiment is substantially the same as the rest of Embodiment 1, except that the thickness of the first protection layer is 20 μm.

### Embodiment 8

This embodiment is substantially the same as the rest of Embodiment 2, except that the thickness of the first protection layer is 20 μm.

### Embodiment 9

This embodiment is substantially the same as the rest of Embodiment 1, except that the thickness of the first protection layer is 30 μm.

### Embodiment 10

This embodiment is substantially the same as the rest of Embodiment 2, except that the thickness of the first protection layer is 30 μm.

### Comparative Embodiment 1

Comparative Embodiment 1 is substantially the same as the rest of Embodiment 1, except that the content of diffusion particles is 0.05 wt %.

### Comparative Embodiment 2

Comparative Embodiment 2 is substantially the same as the rest of Embodiment 2, except that the content of diffusion particles is 0.05 wt %.

### Comparative Embodiment 3

Comparative Embodiment 3 is substantially the same as the rest of Embodiment 1, except that the content of diffusion particles is 1.0 wt %.

### Comparative Embodiment 4

Comparative Embodiment 4 is substantially the same as the rest of Embodiment 2, except that the content of diffusion particles is 1.0 wt %.

The experimental data of Embodiment 1 to Embodiment 10 and the experimental data of Comparative Embodiment 1 to Comparative Embodiment 4 are compiled in Table 1 and Table 2 below.

TABLE 1
Diffusion particles (zinc oxide) added to
the first protection layer of the backsheet

| | | Thick- | Light | Light spot | |
|---|---|---|---|---|---|
| | Content of | ness of | transmit- | size gain | Haze |
| | diffusion | the pro- | tance of | value of | of the |
| | parti- | tection | the back- | the back- | back- |
| | cles | layer | sheet | sheet | sheet |
| | (wt %) | (μm) | (%) | (%) | (%) |
| Embodiment 1 | 0.1 | 10 | 89.65 | 26.26 | 4.48 |
| Embodiment 3 | 0.3 | 10 | 89.61 | 36.57 | 5.25 |
| Embodiment 5 | 0.5 | 10 | 89.52 | 40.87 | 6.31 |
| Embodiment 7 | 0.1 | 20 | 89.55 | 28.32 | 4.25 |
| Embodiment 9 | 0.1 | 30 | 89.40 | 30.57 | 4.94 |
| Comparative | 0.05 | 10 | 89.64 | 13.85 | 4.15 |
| Embodiment 1 | | | | | |
| Comparative | 1.0 | 10 | 88.19 | 144.65 | 20.09 |
| Embodiment 3 | | | | | |

TABLE 2
Diffusion particles (zinc oxide) added to the
second protection layer of the backsheet

| | | Thick- | Light | Light spot | |
|---|---|---|---|---|---|
| | Content of | ness of | transmit- | size gain | Haze |
| | diffusion | the pro- | tance of | value of | of the |
| | parti- | tection | the back- | the back- | back- |
| | cles | layer | sheet | sheet | sheet |
| | (wt %) | (μm) | (%) | (%) | (%) |
| Embodiment 2 | 0.1 | 10 | 89.65 | 22.22 | 4.48 |
| Embodiment 4 | 0.3 | 10 | 89.61 | 28.88 | 5.25 |
| Embodiment 6 | 0.5 | 10 | 89.52 | 34.75 | 6.31 |
| Embodiment 8 | 0.1 | 20 | 89.55 | 25.11 | 4.25 |
| Embodiment 10 | 0.1 | 30 | 89.40 | 27.36 | 4.94 |
| Comparative | 0.05 | 10 | 89.64 | 13.32 | 4.15 |
| Embodiment 2 | | | | | |
| Comparative | 1.0 | 10 | 88.19 | 61.01 | 20.09 |
| Embodiment 4 | | | | | |

From Table 1 and Table 2 (Embodiment 1 to Embodiment 6 and Comparative Embodiment 1 to Comparative Embodiment 4) and the aforementioned Experimental Example 1, it may be seen that when the content of diffusion particles (zinc oxide) is less than or equal to 0.5 wt %, the backsheet of the solar cell module may have a light transmittance greater than 89%, and when the content of diffusion particles (zinc oxide) is greater than or equal to 0.1 wt %, the backsheet of the solar cell module may have a light spot size gain value greater than 20%. That is, when the content of the diffusion particles (zinc oxide) in the first protection layer or the second protection layer is 0.1 wt % to 0.5 wt %, the backsheet of the solar cell module may simultaneously have a light transmittance greater than 89% and a light spot size gain value greater than 20%.

In addition, as may be seen from Table 1 and Table 2, taking Embodiment 1 and Embodiment as examples, compared with adding diffusion particles to the second protection layer, diffusion particles are added to the first protection layer so that the backsheet of the solar cell module has greater light transmittance and light spot size gain. The reason for this may be, for example, when the diffusion particles are added to the first protection layer, after the light is scattered by the diffusion particles in the first protection layer, the light passes through the substrate, the second protection layer, and the adhesive layer in sequence to reach the battery unit; on the other hand, when the diffusion particles are added to the second protection layer, after the light is scattered by the diffusion particles in the second protection layer, the light only passes through the adhesive layer to reach the battery unit, and the light path that the light travels is shorter, so that light spot size presented on the battery unit is also smaller.

Furthermore, as may be seen from Table 1 and Table 2 (Embodiment 1 to Embodiment 10) that when the thickness of the first protection layer is in the range of 10 μm to 30 μm, the backsheet of the solar cell module may have both a light transmittance greater than 89% and a light spot size gain value greater than 20%.

In addition, as may be seen from Table 1 and Table 2 (Embodiment 1 to Embodiment 10), with the silicone layer as the substrate, when the content of diffusion particles (zinc oxide) is 0.1 wt % to 0.5 wt %, the backsheet of the solar cell module may have low haze.

### Embodiment 11

In this embodiment, the solar cell module has a similar structure and formation as shown in Experimental Example 2, the only difference is that the thickness of the first protection layer is 10 μm, and the diffusion particles are added to the first protection layer, the particle size of the diffusion particles is 1.00 μm, and the content of the diffusion particles is 0.05 wt %. In addition, the light transmittance, the light spot size gain value, and the haze are measured for the backsheet of this embodiment.

### Embodiment 12

This embodiment is substantially the same as the rest of Embodiment 11, except that the diffusion particles are added to the second protection layer.

### Embodiment 13

This embodiment is substantially the same as the rest of Embodiment 11, except that the content of diffusion particles is 0.1 wt %.

### Embodiment 14

This embodiment is substantially the same as the rest of Embodiment 12, except that the content of diffusion particles is 0.1 wt %.

### Embodiment 15

This embodiment is substantially the same as the rest of Embodiment 11, except that the content of diffusion particles is 0.3 wt %.

### Embodiment 16

This embodiment is substantially the same as the rest of Embodiment 12, except that the content of diffusion particles is 0.3 wt %.

### Embodiment 17

This embodiment is substantially the same as the rest of Embodiment 11, except that the thickness of the first protection layer is 20 μm.

### Embodiment 18

This embodiment is substantially the same as the rest of Embodiment 12, except that the thickness of the first protection layer is 20 μm.

### Embodiment 19

This embodiment is substantially the same as the rest of Embodiment 11, except that the thickness of the first protection layer is 30 μm.

### Embodiment 20

This embodiment is substantially the same as the rest of Embodiment 12, except that the thickness of the first protection layer is 30 μm.

### Comparative Embodiment 5

Comparative Embodiment 5 is substantially the same as the rest of Embodiment 11, except that the content of diffusion particles is 0.5 wt %.

### Comparative Embodiment 6

Comparative Embodiment 6 is substantially the same as the rest of Embodiment 12, except that the content of diffusion particles is 0.5 wt %.

The experimental data of Embodiment 11 to Embodiment 20 and the experimental data of Comparative Embodiment 5 to Comparative Embodiment 6 are compiled in Table 3 and Table 4 below.

TABLE 3
Diffusion particles (titanium dioxide modified with silicon
dioxide) added to the first protection layer of the backsheet

| | | Thick- | Light | Light spot | |
|---|---|---|---|---|---|
| | Content of | ness of | transmit- | size gain | Haze |
| | diffusion | the pro- | tance of | value of | of the |
| | parti- | tection | the back- | the back- | back- |
| | cles | layer | sheet | sheet | sheet |
| | (wt %) | (μm) | (%) | (%) | (%) |
| Embodiment 11 | 0.05 | 10 | 89.46 | 25.51 | 4.58 |
| Embodiment 13 | 0.1 | 10 | 89.03 | 43.34 | 6.32 |
| Embodiment 15 | 0.3 | 10 | 89.00 | 49.47 | 7.08 |
| Embodiment 17 | 0.05 | 20 | 89.21 | 30.58 | 5.12 |
| Embodiment 19 | 0.05 | 30 | 89.06 | 40.52 | 5.92 |
| Comparative | 0.5 | 10 | 87.54 | 152.67 | 10.8 |
| Embodiment 5 | | | | | |

TABLE 4
Diffusion particles (titanium dioxide modified with silicon dioxide)
added to the second protection layer of the backsheet

| | | Thick- | Light | Light spot | |
|---|---|---|---|---|---|
| | Content of | ness of | transmit- | size gain | Haze |
| | diffusion | the pro- | tance of | value of | of the |
| | parti- | tection | the back- | the back- | back- |
| | cles | layer | sheet | sheet | sheet |
| | (wt %) | (μm) | (%) | (%) | (%) |
| Embodiment 12 | 0.05 | 10 | 89.46 | 23.11 | 4.58 |
| Embodiment 14 | 0.1 | 10 | 89.03 | 36.23 | 6.32 |
| Embodiment 16 | 0.3 | 10 | 89.00 | 47.33 | 7.08 |
| Embodiment 18 | 0.05 | 20 | 89.21 | 28.74 | 5.12 |
| Embodiment 20 | 0.05 | 30 | 89.06 | 32.44 | 5.92 |
| Comparative | 0.5 | 10 | 87.54 | 137.74 | 10.8 |
| Embodiment 6 | | | | | |

From Table 3 and Table 4 (Embodiment 11 to Embodiment 16 and Comparative Embodiment 5 to Comparative Embodiment 6) and the aforementioned Experimental Example 2, it may be seen that when the content of diffusion particles (titanium dioxide modified with silicon dioxide) is less than or equal to 0.3 wt %, the backsheet of the solar cell module may have a light transmittance greater than 89%, and when the content of diffusion particles (titanium dioxide modified with silicon dioxide) is greater than or equal to 0.05 wt %, the backsheet of the solar cell module may have a light spot size gain value greater than 20%. That is, when the content of the diffusion particles (titanium dioxide modified with silicon dioxide) in the first protection layer or the second protection layer is 0.05 wt % to 0.3 wt %, the backsheet of the solar cell module may simultaneously have a light transmittance greater than 89% and a light spot size gain value greater than 20%.

Furthermore, as may be seen from Table 3 and Table 4 (Embodiment 11 to Embodiment 20) that when the thickness of the first protection layer is in the range of 10 μm to 30 μm, the backsheet of the solar cell module may have both a light transmittance greater than 89% and a light spot size gain value greater than 20%.

In addition, as may be seen from Table 3 and Table 4 (Embodiment 11 to Embodiment 20), with the silicone layer as the substrate, when the content of diffusion particles is 0.05 wt % to 0.3 wt %, the backsheet of the solar cell module may have low haze.

### Comparative Embodiment 7

In Comparative Embodiment 7, the solar cell module has a similar structure and formation as shown in Experimental Example 1, the difference is that the thickness of the first protection layer is 10 μm, the diffusion particles are titanium dioxide (purchased from Proti Chemical Co., Ltd., model: R350), the diffusion particles are added to the first protection layer, the particle size of the diffusion particles is 0.35 μm, and the content of the diffusion particles is 0.1 wt %. In addition, the light transmittance, the light spot size gain value, and the haze are measured for the backsheet of Comparative Embodiment 7.

### Comparative Embodiment 8

Comparative Embodiment 8 is substantially the same as the rest of Comparative Embodiment 7, except that the diffusion particles are added to the second protection layer.

The experimental data of Comparative Embodiment 7 to Comparative Embodiment 8 are compiled in Table 5 below.

TABLE 5
Diffusion particles (titanium dioxide) added to the backsheet

| | | Thick- | Light | Light spot | |
|---|---|---|---|---|---|
| | Content of | ness of | transmit- | size gain | Haze |
| | diffusion | the pro- | tance of | value of | of the |
| | parti- | tection | the back- | the back- | back- |
| | cles | layer | sheet | sheet | sheet |
| | (wt %) | (μm) | (%) | (%) | (%) |
| Comparative | 0.1 | 10 | 88.02 | 88.27 | 10.64 |
| Embodiment 7 | | | | | |
| (Added to the | | | | | |
| first protection | | | | | |
| layer) | | | | | |
| Comparative | 0.1 | 10 | 88.02 | 66.52 | 10.64 |
| Embodiment 8 | | | | | |
| (Added to the | | | | | |
| second | | | | | |
| protection layer) | | | | | |

As seen from Table 5, when the diffusion particles are titanium dioxide, although the backsheet of the solar cell module may have a light spot size gain value greater than 20%, it does not have a light transmittance greater than 89%.

### Comparative Embodiment 9

In Comparative Embodiment 9, the solar cell module has a similar structure and formation as shown in Comparative Experimental Example, the difference is that the thickness of the first protection layer is 10 μm, the diffusion particles are silicon oxide, the diffusion particles are added to the first protection layer, the particle size of the diffusion particles is 3.00 μm, and the content of the diffusion particles is 0.1 wt %. In addition, the light transmittance, the light spot size gain value, and the haze are measured for the backsheet of Comparative Embodiment 9.

### Comparative Embodiment 10

Comparative Embodiment 10 is substantially the same as the rest of Comparative Embodiment 9, except that the diffusion particles are added to the second protection layer.

### Comparative Embodiment 11

Comparative Embodiment 11 is substantially the same as the rest of Comparative Embodiment 9, except that the content of diffusion particles is 0.5 wt %.

### Comparative Embodiment 12

Comparative Embodiment 12 is substantially the same as the rest of Comparative Embodiment 10, except that the content of diffusion particles is 0.5 wt %.

### Comparative Embodiment 13

Comparative Embodiment 13 is substantially the same as the rest of Comparative Embodiment 9, except that the content of diffusion particles is 1.0 wt %.

### Comparative Embodiment 14

Comparative Embodiment 14 is substantially the same as the rest of Comparative Embodiment 10, except that the content of diffusion particles is 1.0 wt %.

The experimental data of Comparative Embodiment 9 to Comparative Embodiment 14 are compiled in Table 6 and Table 7 below.

TABLE 6
Diffusion particles (silicon dioxide) added to
the first protection layer of the backsheet

| | | Thick- | Light | Light spot | |
|---|---|---|---|---|---|
| | Content of | ness of | transmit- | size gain | Haze |
| | diffusion | the pro- | tance of | value of | of the |
| | parti- | tection | the back- | the back- | back- |
| | cles | layer | sheet | sheet | sheet |
| | (wt %) | (μm) | (%) | (%) | (%) |
| Comparative | 0.1 | 10 | 89.51 | 10.79 | 4.52 |
| Embodiment 9 | | | | | |
| Comparative | 0.5 | 10 | 89.74 | 12.79 | 5.33 |
| Embodiment 11 | | | | | |
| Comparative | 1.0 | 10 | 89.65 | 11.66 | 5.02 |
| Embodiment 13 | | | | | |

TABLE 7
Diffusion particles (silicon dioxide) added to
the second protection layer of the backsheet

| | | Thick- | Light | Light spot | |
|---|---|---|---|---|---|
| | Content of | ness of | transmit- | size gain | Haze |
| | diffusion | the pro- | tance of | value of | of the |
| | parti- | tection | the back- | the back- | back- |
| | cles | layer | sheet | sheet | sheet |
| | (wt %) | (μm) | (%) | (%) | (%) |
| Comparative | 0.1 | 10 | 89.51 | 10.66 | 4.52 |
| Embodiment 10 | | | | | |
| Comparative | 0.5 | 10 | 89.74 | 11.79 | 5.33 |
| Embodiment 12 | | | | | |
| Comparative | 1.0 | 10 | 89.65 | 10.79 | 5.02 |
| Embodiment 14 | | | | | |

It may be seen from FIG. 6, FIG. 7, and the aforementioned Comparative Experimental Example that when the diffusion particles are silicon dioxide, no matter how the content of diffusion particles is adjusted, although the backsheet of the solar cell module may have a light transmittance greater than 89%, it does not have a light spot size gain value greater than 20%. The reason is that the difference in refractive index between silicon dioxide and the silicone resin layer is only 0.017, so there is no light diffusion effect.

To sum up, the disclosure provides a backsheet of a solar cell module, which includes a first protection layer away from the battery units and a second protection layer facing the battery units. By adding specific diffusion particles to at least one of the first protection layer and the second protection layer, the intensity and uniformity of light incident on the battery units through the backplane may be improved, so that the amount of light received by the battery units may be increased, thereby improving the light conversion efficiency of solar cell modules. In addition, in the disclosure, by selecting specific diffusion particles, defining the added content of diffusion particles, and designing the thicknesses of the first protection layer and the second protection layer, the backsheet of the solar cell module may have a light transmittance greater than 89% and a light spot size gain value greater than 20%.

Furthermore, the disclosure uses the silicone layer as the base of the first protection layer and the second protection layer, compared with the fluorine-containing resin layer, the silicone layer is not only weather resistant, but also reduces pollution to the environment. In addition, the disposition of the silicone layer does not increase the haze of the solar cell module and may maintain the transparency of the backsheet.

1. A backsheet of a solar cell module, comprising:
a substrate, comprising a first surface and a second surface opposite to each other;
a first protection layer, disposed on the first surface of the substrate; and
a second protection layer, disposed on the second surface of the substrate,
wherein the first protection layer and the second protection layer comprise a silicone layer, and at least one of the first protection layer and the second protection layer comprises diffusion particles,
wherein the diffusion particles comprise zinc oxide, titanium dioxide modified with silicon dioxide, or a combination thereof,
wherein a thickness of the first protection layer and a thickness of the second protection layer are respectively 10 μm to 30 μm,
wherein the solar cell module is a bifacial solar cell module.

2. The backsheet of the solar cell module according to claim 1, wherein a content of the diffusion particles in the first protection layer or the second protection layer is 0.05 wt % to 0.5 wt %.

3. The backsheet of the solar cell module according to claim 2, wherein when the diffusion particles comprises zinc oxide, the content of the diffusion particles in the first protection layer or the second protection layer is 0.1 wt % to 0.5 wt %.

4. The backsheet of the solar cell module according to claim 2, wherein when the diffusion particles comprises titanium dioxide modified with silicon dioxide, the content of the diffusion particles in the first protection layer or the second protection layer is 0.05 wt % to 0.3 wt %.

5. The backsheet of the solar cell module according to claim 1, wherein a particle size range of the diffusion particles is 0.5 μm to 5 μm.

6. The backsheet of the solar cell module according to claim 1, wherein a difference between a refractive index of the diffusion particles and a refractive index of the silicone layer is greater than 0.3.

7. The backsheet of the solar cell module according to claim 1, wherein the silicone layer comprises polysiloxane resin, silicone, or a combination thereof.

8. The backsheet of the solar cell module according to claim 1, wherein a material of the substrate comprises ethylene terephthalate, poly(methyl methacrylate), or a combination thereof.

9. The backsheet of the solar cell module according to claim 1, wherein a thickness of the substrate is greater than or equal to 250 μm.

10. A solar cell module, comprising:
a battery unit;
a backsheet, disposed on the battery unit and comprising:
a substrate, comprising a first surface and a second surface opposite to each other, wherein the second surface faces the battery unit;
a first protection layer, disposed on the first surface of the substrate; and
a second protection layer, disposed on the second surface of the substrate; and
an adhesive layer, disposed between the battery unit and the second protection layer,
wherein the first protection layer and the second protection layer comprise a silicone layer, and at least one of the first protection layer and the second protection layer comprises diffusion particles,
wherein the diffusion particles comprise zinc oxide, titanium dioxide modified with silicon dioxide, or a combination thereof,
wherein a thickness of the first protection layer and a thickness of the second protection layer are 10 μm to 30 μm,
wherein the solar cell module is a bifacial solar cell module.
